(19) United States
(12) Patent Application Publication
(10) Pub. No.: US 2016/0329527 A1
(43) Pub. Date: Nov. 10, 2016

(54) LIGHT-EMITTING DIODE DISPLAY PANEL AND METHOD OF FABRICATING SAME

(71) Applicants: BOE TECHNOLOGY GROUP CO., LTD., Beijing (CN); CHENGDU BOE OPTOELECTRONICS TECHNOLOGY CO., LTD., Chengdu (CN)

(72) Inventors: Falu YANG, Beijing (CN); Junrui ZHANG, Beijing (CN)

(21) Appl. No.: 14/777,576

(22) PCT Filed: Jan. 13, 2015
(86) PCT No.: PCT/CN15/70616

§ 371 Date: Sep. 16, 2015

(30) Foreign Application Priority Data
Sep. 23, 2014 (CN) 201410492129.9

(51) Int. Cl. H01L 51/52; G02B 5/30; H01L 51/56

(52) U.S. Cl. CPC H01L 51/5293; H01L 51/56; G02B 5/3058; G02B 5/3016; G02B 5/3033

(57) ABSTRACT

The present disclosure relates to the field of display technology, and discloses a light-emitting diode display panel and a method of fabricating same. The light-emitting diode display panel comprises a first substrate, a second substrate, a polarizer layer and a λ/4 phase retarder film, the polarizer layer and the λ/4 phase retarder film being arranged such that incident ambient light passes in turn through the polarizer layer and the λ/4 phase retarder film to arrive at the first substrate. The present disclosure effectively prevents the impact of reflection of the ambient light on the displayed image and thus improves the display quality, by arranging both the polarizer layer and the λ/4 phase retarder film in the light-emitting diode display panel.

### RELATED APPLICATIONS

The present application is the U.S. national phase entry of PCT/CN2015/070616, with an international filing date of Jan. 13, 2015, which claims the benefit of Chinese Patent Application No. 201410492129.9 filed Sep. 23, 2014, the entire disclosures of which are incorporated herein by reference.

### FIELD OF THE DISCLOSURE

The present disclosure relates to the field of display technology, and more particularly to a light-emitting diode display panel and a method of fabricating same.

### BACKGROUND OF THE DISCLOSURE

The light-emitting diode display panel stands for a trend for development of display products, especially the organic light-emitting display panel, which has a range of advantages such as being wide in viewing angle, fast in response speed, high in brightness, high in contrast, bright in colors, light in weight, thin in thickness, low in power consumption, and the like.

FIG. 1 is a structural schematic diagram of an existing light-emitting diode display panel. The light-emitting diode display panel comprises a first substrate 1 and a second substrate 2. The first substrate 1 contains inherent constructions of a light-emitting diode display panel such as an anode, a cathode, a light-emitting layer, a color filter layer, a hole injection layer, a hole transporting layer, an electron transporting layer, a protective film and the like. The light-emitting diode display panel as illustrated in FIG. 1 is readily affected by ambient light, since a region where metal is contained in the first substrate 1 (i.e., a metallic region) reflects a 100% of the ambient light as indicated by the arrow in FIG. 1, which has a significant impact on a light path and colors of the light-emitting diode display panel, thereby affecting the display quality.

At present, a common improvement approach is to provide a polarizer 3 at an outer side of the second substrate 2 as illustrated in FIG. 2. The ambient light is converted into linear polarized light after passing through the polarizer 3, and exits as linear polarized light after being reflected by the metallic region with a reflective index of about 50%. While the light-emitting diode display panel has a somewhat decreased reflective index for the ambient light when being provided with the polarizer 3, about 50% of the ambient light that is reflected still has an impact on the display quality.

### SUMMARY OF THE DISCLOSURE

It is an object of the present disclosure to provide a light-emitting diode display panel and a method of fabricating the same to reduce an impact of ambient light on display quality.

To address this, the present disclosure provides a light-emitting diode display panel comprising a first substrate, a second substrate and a polarizer layer, the light-emitting diode display panel further comprising a λ/4 phase retarder film. The polarizer layer and the λ/4 phase retarder film are arranged such that incident ambient light passes in turn through the polarizer layer and the λ/4 phase retarder film to arrive at the first substrate.

In some embodiments, an angle between a transmission axis of the polarizer layer and a transmission axis of the λ/4 phase retarder film is 45°.

In some embodiments, the polarizer layer is arranged at a surface of the second substrate away from the first substrate, and the λ/4 phase retarder film is arranged at a surface of the second substrate adjacent to the first substrate.

In some embodiments, the polarizer layer is a polarizer.

In some embodiments, the polarizer layer and the λ/4 phase retarder film are arranged in turn at a surface of the second substrate adjacent to the first substrate.

In some embodiments, the polarizer layer is a metallic grating layer for converting the ambient light into linear polarized light.

In some embodiments, the polarizer layer is a dichroic dye molecule layer for converting the ambient light into linear polarized light.

In some embodiments, a dichroic dye molecule forming the dichroic dye molecule layer comprises at least one of an azo group dichroic dye molecule and an anthraquinonyl dichroic dye molecule.

In some embodiments, the λ/4 phase retarder film comprises an alignment layer and a liquid crystal polymer layer arranged over the alignment layer, an angle between an alignment direction of the alignment layer and a transmission axis of the polarizer layer being 45°.

In some embodiments, the polarizer layer has a pattern corresponding to a pattern of a metallic region in the first substrate.

The present disclosure also provides a method of fabricating a light-emitting diode display panel, the light-emitting diode display panel comprising a first substrate and a second substrate, the method comprising steps of:

arranging a polarizer layer at a surface of the second substrate away from the first substrate, and arranging a λ/4 phase retarder film at a surface of the second substrate adjacent to the first substrate;

or, arranging a polarizer layer and a λ/4 phase retarder film in turn at a surface of the second substrate adjacent to the first substrate;

or, arranging a λ/4 phase retarder film and a polarizer layer in turn at a surface of the second substrate away from the first substrate; and

cutting the second substrate and the first substrate for cell alignment;

wherein the polarizer layer and the λ/4 phase retarder film are arranged such that incident ambient light passes in turn through the polarizer layer and the λ/4 phase retarder film to arrive at the first substrate.

In some embodiments, an angle between a transmission axis of the polarizer layer and a transmission axis of the λ/4 phase retarder film is 45°.

The present disclosure effectively prevents the impact of reflection of the ambient light on the displayed image and thus improves the display quality, by arranging both the polarizer layer and the λ/4 phase retarder film in the light-emitting diode display panel.

### BRIEF DESCRIPTION OF THE DRAWINGS

The accompanying drawings are provided for a better understanding of the present disclosure, which form a part of the specification for illustration and not limitation of the present disclosure in connection with the detailed description below. In the drawings:

FIG. 1 is a structural schematic diagram of an existing light-emitting diode display panel;

FIG. 2 is a structural schematic diagram of another existing light-emitting diode display panel;

FIG. 3 is a structural schematic diagram of a light-emitting diode display panel according to an embodiment of the present disclosure;

FIG. 4 is a schematic diagram of a light path of the construction as shown in FIG. 3;

FIG. 5 is a plan view of a polarizer layer of FIG. 3;

FIG. 6 is a plan view of a liquid crystal polymer layer of FIG. 3;

FIG. 7 is a structural schematic diagram of a light-emitting diode display panel according to another embodiment of the present disclosure;

FIG. 8 is a schematic diagram of a light path of the construction as shown in FIG. 7; and

FIG. 9 is a plan view of a polarizer layer having a pattern.

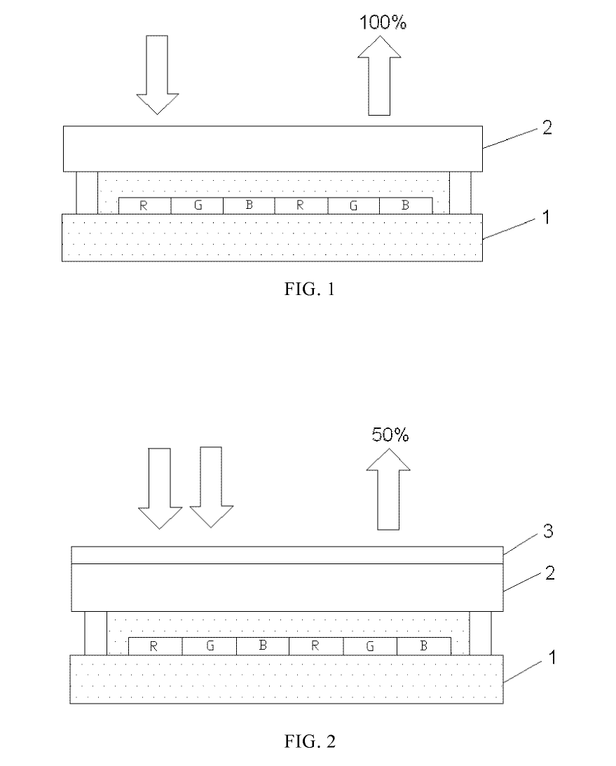

### DETAILED DESCRIPTION

Embodiments of the present disclosure are described in detail in connection with the accompanying drawings. It is to be understood that the described embodiments herein are for illustration and explanation purposes only, and not for limitation of the present disclosure.

The present disclosure provides a light-emitting diode display panel comprising a first substrate, a second substrate and a polarizer layer, the light-emitting diode display panel further comprising a λ/4 phase retarder film. The polarizer layer and the λ/4 phase retarder film are arranged such that incident ambient light arrives at the first substrate after passing through the polarizer layer and the λ/4 phase retarder film in turn.

The light-emitting diode display panel may be an organic light-emitting diode (OLED) display panel, or it may be an active matrix organic light-emitting diode (AMOLED) display panel. In some embodiments, the first substrate may be used for display, and the second substrate may be used for encapsulation of the first substrate. For example, the first substrate may be a display substrate which contains constructions such as an anode, a cathode, a light-emitting layer, a color filter layer, a hole injection layer, a hole transporting layer, an electron transporting layer, an array of thin-film transistors, a protective film, and the like. The second substrate may be a cover plate for encapsulation purpose only. A plurality of constructions in the first substrate, such as the anode, the cathode, the array of thin-film transistors and the like, contain metallic materials, and the region where the metallic materials are located is referred to here as a metallic region. The metallic region in the first substrate can reflect ambient light incident on the first substrate, and thus has an impact on the display effect.

In the present disclosure, the incident ambient light is converted into linear polarized light after passing through the polarizer layer, and into circular polarized light or elliptical polarized light after passing through the λ/4 phase retarder film. If an angle between a transmission axis of the polarizer layer and a transmission axis of the λ/4 phase retarder film is 45°, the circular polarized light is produced. Otherwise, the elliptical polarized light is produced. A change in handedness occurs to the circular polarized light or elliptical polarized light when it arrives at the first substrate and is reflected by the metallic region. For example, left-handed circular polarized light will be converted into right-handed circular polarized light, and then into linear polarized light, with polarization perpendicular to the previous polarization after passing again through the λ/4 phase retarder film. Thus, it cannot transmit through the polarizer layer. Therefore, the impact of reflection of the ambient light on the displayed image is significantly reduced, resulting in an improved display quality.

Preferably, the angle between the transmission axis of the polarizer layer and the transmission axis of the λ/4 phase retarder film is 45°. In this case, the exiting ambient light comprises only linear polarized light whose polarization is perpendicular to the transmission axis of the polarizer layer, such that no ambient light can transmit through the polarizer layer (i.e. a reflective index of the incident ambient light is 0%, leading to avoidance of the impact of the ambient light on the display quality).

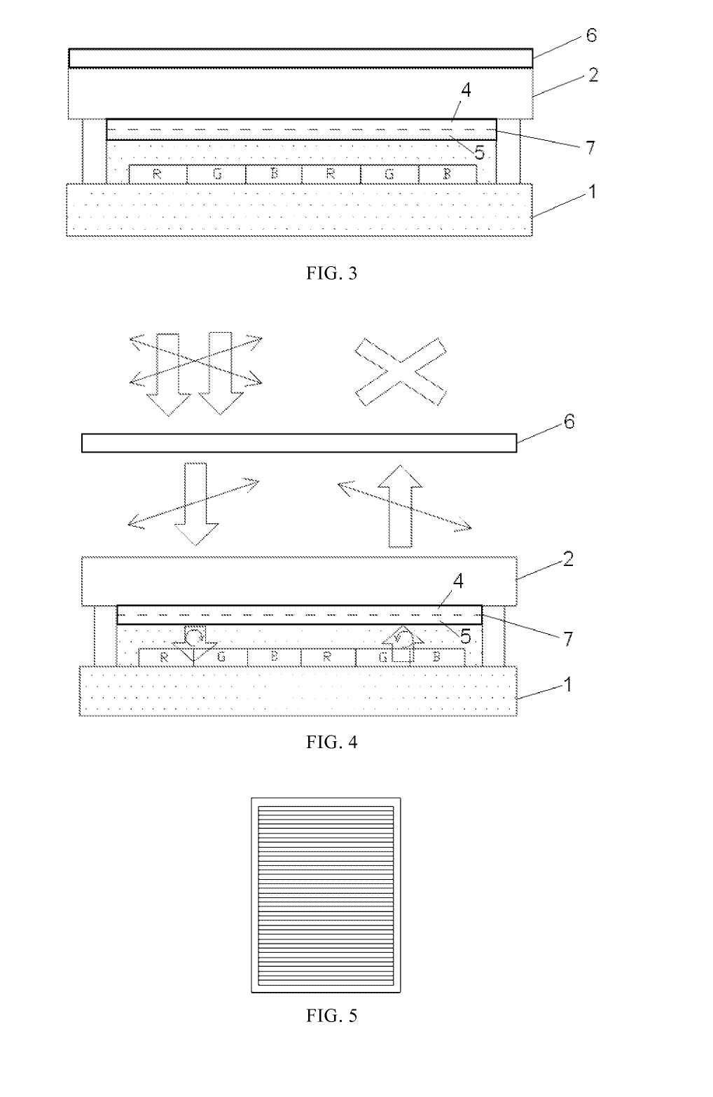

FIG. 3 is a structural schematic diagram of a light-emitting diode display panel according to an embodiment of the present disclosure. In FIG. 3, the polarizer layer 6 is arranged at a surface of the second substrate 2 away from the first substrate 1 (i.e., at an outer side of the second substrate 2), and the λ/4 phase retarder film 7 is arranged at a surface of the second substrate 2 adjacent to the first substrate 1 (i.e., at an inner side of the second substrate 2). The ambient light is incident from above the polarizer layer 6 and passes in turn through the polarizer layer 6, the second substrate 2 and the λ/4 phase retarder film 7 to shine on the first substrate 1.

The polarizer layer 6 in this embodiment is not limited to any specific form, as long as it can convert the ambient light into linear polarized light. The polarizer layer 6 in FIG. 3 is arranged at the outer side of the second substrate 2, in which case the polarizer layer 6 is preferably a conventional polarizer so as to simplify the manufacture procedure and to save the cost.

The λ/4 phase retarder film 7 may be achieved by forming an alignment layer 4 and a liquid crystal polymer layer 5 in turn at the inner side of the second substrate 2. With the angle between the transmission axis of the polarizer layer 6 and the transmission axis of the λ/4 phase retarder film 7 being preferably 45°, an angle between an alignment direction of the alignment layer 4 and the transmission axis of the polarizer layer 6 may be arranged to be 45°.

The alignment layer 4 may be formed by way of friction, or it may be formed by way of photo-induced alignment. The liquid crystal polymer layer 5 is formed by liquid crystal reactive monomers through ultraviolet curing.

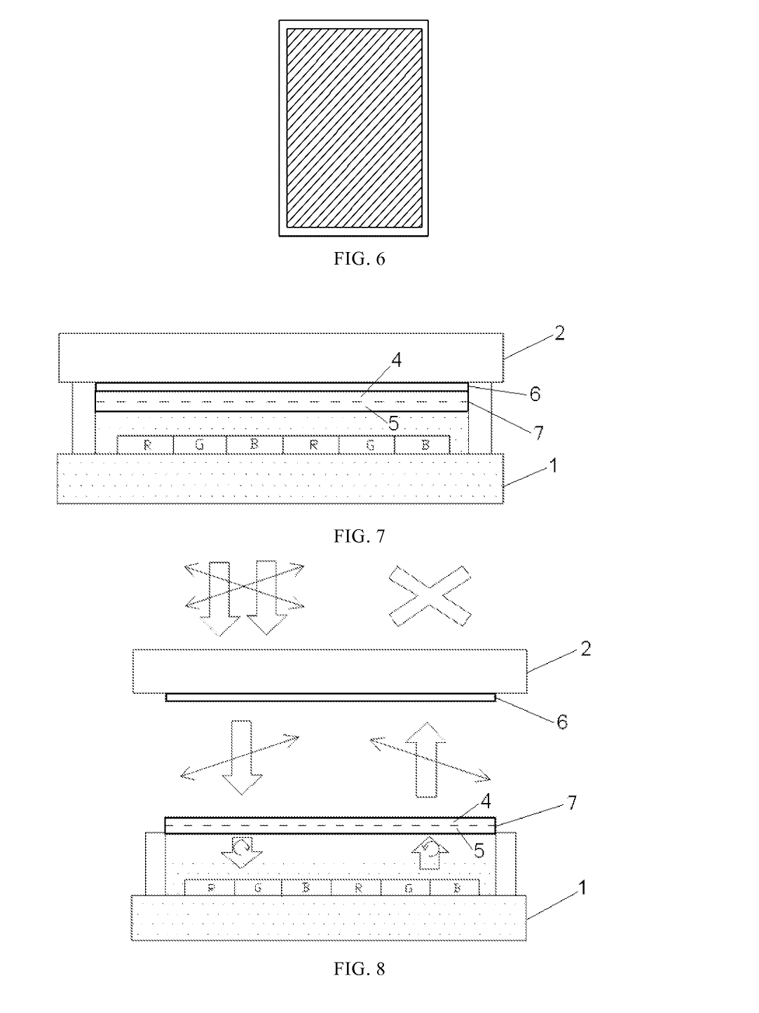

FIG. 4 is a schematic diagram of a light path of the construction as shown in FIG. 3. Assuming that the transmission axis of the polarizer layer 6 is at 0°, then the incident ambient light is converted into linear polarized light of 0° after passing through the polarizer layer 6 as shown in FIG. 5. The transmission axis of the λ/4 phase retarder film 7 is preferably orientated at 45° to form an angle of 45° with the transmission axis of the polarizer layer 6. Here the alignment direction of the alignment layer 4 may be arranged to be 45°, and then the liquid crystal polymer layer 5 may be arranged over the alignment layer 4. A plan view of the arranged liquid crystal polymer layer 5 is shown in FIG. 6.

Upon passing through the λ/4 phase retarder film 7 formed by the alignment layer 4 and the liquid crystal polymer layer 5, the linear polarized light of 0° is converted into left-handed circular polarized light. The left-handed circular polarized light is then converted into right-handed circular polarized light upon reflection by the metallic region in the first substrate 1. Upon passing again through the λ/4 phase retarder film 7, the right-handed circular polarized light is converted into linear polarized light of 90° that cannot transmit through the polarizer layer 6 with a transmission axis of 0°, resulting in a reflective index of 0% against the incident ambient light. This eliminates the impact of reflection of the ambient light on the display effect of the display panel, and hence improves the display quality.

FIG. 7 is a schematic diagram of a light-emitting diode display panel according to another embodiment of the present disclosure. In FIG. 7, the polarizer layer 6 and the λ/4 phase retarder film 7 are arranged in turn at a surface of the second substrate 2 adjacent to the first substrate 1 (i.e., at the inner side of the second substrate 2). The ambient light is incident from above the second substrate 2, passing in turn through the second substrate 2, the polarizer layer 6 and the λ/4 phase retarder film 7 to shine on the first substrate 1.

The polarizer layer 6 in this embodiment is not limited to any specific form, as long as it can convert the ambient light into linear polarized light. The polarizer layer 6 in FIG. 7 is arranged at the inner side of the second substrate 2, in which case the polarizer layer 6 is preferably a metallic grating layer or dichroic dye molecule layer capable of converting the ambient light into linear polarized light. A thin metallic grating layer or dichroic dye molecule layer facilitates restriction of the thickness of the display panel as a whole, allowing it to be in line with the trend of light weight.

For a dichroic dye molecule, it can absorb one of the two orthogonal components of the linear polarization in the incident ambient light, allowing the other one to transmit. Therefore, the dichroic dye molecule layer may achieve a function of light conversion in place of a polarizer. In the present disclosure, a dichroic dye molecule forming the dichroic dye molecule layer may be any of an azo group dichroic dye molecule and an anthraquinonyl dichroic dye molecule or combination thereof.

The molecular formula of the azo group dichroic dye molecule is shown as follows:

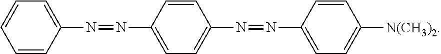 [SMILES: CN(C)c1ccc(N=Nc2ccc(N=Nc3ccccc3)cc2)cc1]

The molecular formula of the anthraquinonyl dichroic dye molecule is shown as follows:

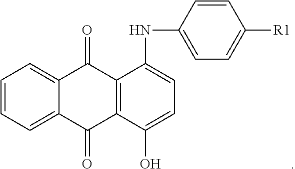

In the embodiment as shown in FIG. 7, the λ/4 phase retarder film 7 can be achieved by forming, in turn, the alignment layer 4 and the liquid crystal polymer layer 5 over the polarizer layer 6. With the angle between the transmission axis of the polarizer layer 6 and the transmission axis of the λ/4 phase retarder film 7 being preferably 45°, the angle between the alignment direction of the alignment layer 4 and the transmission axis of the polarizer layer 6 may be arranged to be 45°.

Likewise, the alignment layer 4 may be formed by way of friction, or it may be formed by way of photo-induced alignment. The liquid crystal polymer layer 5 is formed by liquid crystal reactive monomers through ultraviolet curing.

FIG. 8 is a schematic diagram of a light path of the construction as shown in FIG. 7. Assuming that the transmission axis of the polarizer layer 6 is at 0°, then the incident ambient light is converted into linear polarized light of 0° after passing through the polarizer layer 6. The transmission axis of the λ/4 phase retarder film 7 is preferably orientated at 45° to form an angle of 45° with the transmission axis of the polarizer layer 6. Here, the alignment direction of the alignment layer 4 may be arranged to be 45°, and then the liquid crystal polymer layer 5 may be arranged over the alignment layer 4, forming the λ/4 phase retarder film 7 with a transmission axis of 45°.

Upon passing through the λ/4 phase retarder film 7 formed by the alignment layer 4 and the liquid crystal polymer layer 5, the linear polarized light of 0° is converted into left-handed circular polarized light.

The left-handed circular polarized light is then converted into right-handed circular polarized light upon reflection by the metallic region in the first substrate 1. Upon passing again through the λ/4 phase retarder film 7, the right-handed circular polarized light is converted into linear polarized light of 90° that cannot transmit through the polarizer layer 6 with a transmission axis of 0°, resulting in a reflective index of 0% against the incident ambient light. This eliminates the impact of reflection of the ambient light on the display effect of the display panel, and hence improves the display quality.

In the present disclosure, the arrangement of the λ/4 phase retarder film and the polarizer layer is not limited to any specific configuration, as long as the ambient light passes in turn through the polarizer layer and the λ/4 phase retarder film to arrive at the first substrate or the metallic region therein. For example, the λ/4 phase retarder film and the polarizer layer may also be arranged in turn at the outer side of the second substrate, i.e., the λ/4 phase retarder film is firstly arranged at the outer side of the second substrate, and then the polarizer layer is arranged at outer side of the λ/4 phase retarder film. The principle of the light path is the same as the above-mentioned two embodiments, which will not be discussed here in detail. Furthermore, since the polarizer layer is arranged at the outer side of the second substrate, it is preferably in a form of a polarizer.

Further, the polarizer layer in the present disclosure may have a pattern that corresponds to a pattern of the metallic region in the first substrate. As mentioned above, a plurality of constructions in the first substrate, such as the anode, the cathode, the array of thin-film transistors and the like, contain metallic materials, with the region where the metallic materials are located being referred to as the metallic region. The metallic region generally has a predetermined pattern. Where the pattern of the polarizer layer corresponds to the pattern of the metallic region in the first substrate, a brightness of the display panel can be increased, and materials for fabricating the polarizer layer can be saved.

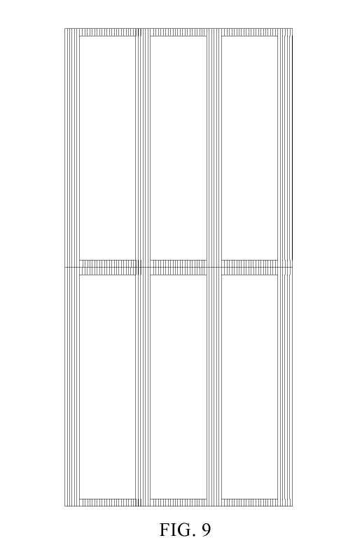

In the present disclosure, the pattern of the polarizer layer may correspond to the pattern of a metallic region formed by metallic material in a certain layered construction of the first substrate, or it may correspond to an accumulation of patterns of the metallic regions formed by all the metallic materials in the first substrate. For example, FIG. 9 is a plan view of a polarizer layer having a pattern, in which the pattern of the polarizer layer corresponds to a periphery of a display region, and to a metallic region formed by the metallic electrodes in the array of thin-film transistors.

The present disclosure also provides in another aspect a method of fabricating the above-mentioned light-emitting diode display panel, the light-emitting diode display panel comprising a first substrate and a second substrate, the method comprising steps of:

Step 1: arranging a polarizer layer at a surface of the second substrate away from the first substrate (i.e., at an outer side of the second substrate), and arranging a λ/4 phase retarder film at a surface of the second substrate adjacent to the first substrate (i.e., at an inner side of the second substrate);

or, arranging a polarizer layer and a λ/4 phase retarder film in turn at an inner side of the second substrate;

or, arranging a λ/4 phase retarder film and a polarizer layer in turn at an outer side of the second substrate; and

Step 2: cutting the second substrate and the first substrate for cell alignment;

wherein the polarizer layer and the λ/4 phase retarder film are arranged such that incident ambient light passes in turn through the polarizer layer and the λ/4 phase retarder film to arrive at the first substrate.

Preferably, an angle between a transmission axis of the polarizer layer and a transmission axis of the λ/4 phase retarder film is 45°.

The incident ambient light is converted into linear polarized light after passing through the polarizer layer, and into circular polarized light after passing through the λ/4 phase retarder film. A change in handedness occurs to the circular polarized light when it arrives at the first substrate and is reflected by a metallic region in the first substrate. For example, left-handed circular polarized light will be converted into right-handed circular polarized light, and then into linear polarized light whose polarization is perpendicular to the previous polarization after passing again through the λ/4 phase retarder film, and thus it cannot transmit through the polarizer layer. The present disclosure effectively reduces the impact of reflection of the ambient light on the displayed image, resulting in an improved display quality.

The polarizer layer may be a polarizer, a metallic grating layer, a dichroic dye molecule layer, or any other layered construction that is able to convert the ambient light into linear polarized light. In case the polarizer layer is arranged at the outer side of the second substrate, it is preferably a polarizer for purpose of a reduced difficulty of process and a saved cost. In case the polarizer layer is arranged at the inner side of the second substrate, it is preferably a metallic grating layer or a dichroic dye molecule layer so as to maintain the thickness of the display panel at a low level.

The λ/4 phase retarder film may comprise an alignment layer and a liquid crystal polymer layer arranged over the alignment layer, with the liquid crystal polymer layer formed by liquid crystal reactive monomers through ultraviolet curing. Preferably, an angle between an alignment direction of the alignment layer and a transmission axis of the polarized layer is 45°.

The present disclosure effectively prevents the impact of reflection of the ambient light on the displayed image and thus improves the display quality, by arranging both the polarizer layer and the λ/4 phase retarder film in the light-emitting diode display panel.

It is to be understood that the embodiments above are exemplary embodiments for illustration of the principle of the present disclosure only; however, the present disclosure is not limited thereto. Various variations and modifications can be made by the skilled in the art without departing from the spirit and scope of the present disclosure, which are considered within the protection scope of the present disclosure.

What is claimed is:

1-12. (canceled)

13. A light-emitting diode display panel, comprising:
a first substrate;
a second substrate;
a polarizer layer; and
a λ/4 phase retarder film,
wherein the polarizer layer and the λ/4 phase retarder film are arranged such that incident ambient light passes in turn through the polarizer layer and the λ/4 phase retarder film to arrive at the first substrate.

14. The light-emitting diode display panel as recited in claim 13, wherein an angle between a transmission axis of the polarizer layer and a transmission axis of the λ/4 phase retarder film is 45°.

15. The light-emitting diode display panel as recited in claim 13, wherein the polarizer layer is arranged at a surface of the second substrate away from the first substrate, and wherein the λ/4 phase retarder film is arranged at a surface of the second substrate adjacent to the first substrate.

16. The light-emitting diode display panel as recited in claim 14, wherein the polarizer layer is arranged at a surface of the second substrate away from the first substrate, and wherein the λ/4 phase retarder film is arranged at a surface of the second substrate adjacent to the first substrate.

17. The light-emitting diode display panel as recited in claim 15, wherein the polarizer layer is a polarizer.

18. The light-emitting diode display panel as recited in claim 16, wherein the polarizer layer is a polarizer.

19. The light-emitting diode display panel as recited in claim 13, wherein the polarizer layer and the λ/4 phase retarder film are arranged in turn at a surface of the second substrate adjacent to the first substrate.

20. The light-emitting diode display panel as recited in claim 14, wherein the polarizer layer and the λ/4 phase retarder film are arranged in turn at a surface of the second substrate adjacent to the first substrate.

21. The light-emitting diode display panel as recited in claim 19, wherein the polarizer layer is a metallic grating layer for converting the ambient light into linear polarized light.

22. The light-emitting diode display panel as recited in claim 20, wherein the polarizer layer is a metallic grating layer for converting the ambient light into linear polarized light.

23. The light-emitting diode display panel as recited in claim 19, wherein the polarizer layer is a dichroic dye molecule layer for converting the ambient light into linear polarized light.

24. The light-emitting diode display panel as recited in claim 20, wherein the polarizer layer is a dichroic dye molecule layer for converting the ambient light into linear polarized light.

25. The light-emitting diode display panel as recited in claim 23, wherein a dichroic dye molecule forming the dichroic dye molecule layer comprises at least one of an azo group dichroic dye molecule and an anthraquinonyl dichroic dye molecule.

26. The light-emitting diode display panel as recited in claim 24, wherein a dichroic dye molecule forming the dichroic dye molecule layer comprises at least one of an azo group dichroic dye molecule and an anthraquinonyl dichroic dye molecule.

27. The light-emitting diode display panel as recited in claim 13, wherein the λ/4 phase retarder film comprises an alignment layer and a liquid crystal polymer layer arranged over the alignment layer, an angle between an alignment direction of the alignment layer and a transmission axis of the polarizer layer being 45°.

28. The light-emitting diode display panel as recited in claim 13, wherein the polarizer layer has a pattern corresponding to a pattern of a metallic region in the first substrate.

29. A method of fabricating a light-emitting diode display panel, the light-emitting diode display panel comprising a first substrate and a second substrate, the method comprising steps of:
arranging a polarizer layer at a surface of the second substrate away from the first substrate, and arranging a λ/4 phase retarder film at a surface of the second substrate adjacent to the first substrate;
or, arranging a polarizer layer and a λ/4 phase retarder film in turn at a surface of the second substrate adjacent to the first substrate;
or, arranging a λ/4 phase retarder film and a polarizer layer in turn at a surface of the second substrate away from the first substrate; and
cutting the second substrate and the first substrate for cell alignment;
wherein the polarizer layer and the λ/4 phase retarder film are arranged such that incident ambient light passes in turn through the polarizer layer and the λ/4 phase retarder film to arrive at the first substrate.

30. The method as recited in claim 29, wherein an angle between a transmission axis of the polarizer layer and a transmission axis of the λ/4 phase retarder film is 45°.
